(19) United States
(12) Patent Application Publication
(10) Pub. No.: US 2025/0046663 A1
(43) Pub. Date: Feb. 6, 2025

(54) SEMICONDUCTOR PACKAGE AND METHOD OF MANUFACTURING THE SEMICONDUCTOR PACKAGE

(71) Applicant: SAMSUNG ELECTRONICS CO., LTD., SUWON-SI (KR)

(72) Inventors: Taejun JEON, Suwon-si (KR); Yongkwan LEE, Suwon-si (KR); Seunghwan KIM, Suwon-si (KR); Junwoo PARK, Suwon-si (KR); Gyuhyeong KIM, Suwon-si (KR)

(21) Appl. No.: 18/667,258

(22) Filed: May 17, 2024

(30) Foreign Application Priority Data
Aug. 1, 2023 (KR) 10-2023-0100503

(51) Int. Cl. H01L 23/31; H01L 23/00; H01L 23/64

(52) U.S. Cl. CPC H01L 23/3121; H01L 23/562; H01L 23/564; H01L 23/642; H01L 24/16; H01L 2224/16227

(57) ABSTRACT

A semiconductor package includes a package substrate having a first region, a second region and third region sequentially arranged from a first side portion to a second side portion thereof. The second region has a chip mounting region in a central region. A semiconductor chip is disposed in the chip mounting region and is mounted on a plurality of substrate pads of the package substrate. A pair of first flow control structures is disposed in the first region and is arranged symmetrically on both sides along a center line passing through a center of the chip mounting region. At least one pair of second flow control structures is disposed in the second region of the package substrate and is arranged symmetrically on both sides of the chip mounting region. A molding member is on the package substrate and fills a gap between the semiconductor chip and the package substrate.

### CROSS-REFERENCE TO RELATED APPLICATION

This application claims priority under 35 U.S.C. § 119 to Korean Patent Application No. 10-2023-0100503, filed on Aug. 1, 2023 in the Korean Intellectual Property Office, the disclosure of which is incorporated by reference in its entirety herein.

### 1. TECHNICAL FIELD

Example embodiments of the present inventive concept relate to a semiconductor package and a method of manufacturing the semiconductor package. More particularly, example embodiments of the present inventive concept relate to a semiconductor package including a semiconductor chip mounted by a flip chip method and a manufacturing method thereof.

### 2. DISCUSSION OF RELATED ART

In the manufacture of a flip-chip package, a semiconductor chip may be disposed on a package substrate and a molded under-fil (MUF) process may be performed to form a molding member. In the molded under-fill process, a void trap may occur under the semiconductor chip because a space between a side of the semiconductor chip and a side of the package substrate (e.g., a Chip to PKG Edge) is relatively large compared to a gap (e.g., a Joint Gap) between a lower surface of the semiconductor chip and an upper surface of the package substrate.

### SUMMARY

Example embodiments provide a semiconductor package having a structure preventing a void trap under the semiconductor chip.

Example embodiments provide a method of manufacturing the semiconductor package.

According to an example embodiment, a semiconductor package includes a package substrate having a first region, a second region and third region sequentially arranged from a first side portion thereof to a second side portion thereof. The second region has a chip mounting region in a central region thereof. The package substrate includes a plurality of substrate pads. A semiconductor chip is disposed in the chip mounting region of the package substrate. The semiconductor chip includes a plurality of chip pads. The semiconductor chip is mounted on the plurality of substrate pads of the package substrate via conductive connection members that are disposed on the plurality of chip pads of the semiconductor chip. A pair of first flow control structures is disposed in the first region of the package substrate. The pair of first flow control structures are disposed symmetrically on both sides along a center line passing through a center of the chip mounting region. At least one pair of second flow control structures is disposed in the second region of the package substrate. The at least one pair of second flow control structures are disposed symmetrically on both sides of the chip mounting region. A molding member is on the package substrate. The molding member fills a gap between the semiconductor chip and the package substrate and covers the semiconductor chip, the pair of first flow control structures and the at least one pair of second flow control structures.

According to an example embodiment, a semiconductor package includes a package substrate having a first region, a second region and third region sequentially arranged from a first side portion thereof to a second side portion thereof. The second region having a chip mounting region in a central region thereof. The package substrate including a plurality of substrate pads. A semiconductor chip is disposed in the chip mounting region of the package substrate. The semiconductor chip includes a plurality of chip pads. The semiconductor chip is mounted on the plurality of substrate pads of the package substrate via conductive connection members that are disposed on the plurality of chip pads of the semiconductor chip. A pair of first flow control structures is disposed in the first region of the package substrate. The pair of first flow control structures are disposed symmetrically on both sides along a center line passing through a center of the chip mounting region. A spacing distance between the pair of first flow control structures gradually decreases towards the chip mounting region. A molding member is on the package substrate. The molding member fills a gap between the semiconductor chip and the package substrate and covers the semiconductor chip and the pair of first flow control structures.

According to an example embodiment, a semiconductor package includes a package substrate having a first region, a second region and third region sequentially arranged from a first side portion thereof to a second side portion thereof. The second region has a chip mounting region in a central region thereof. The package substrate includes a plurality of substrate pads. A semiconductor chip is disposed in the chip mounting region of the package substrate. The semiconductor chip includes a plurality of chip pads. The semiconductor chip is mounted on the plurality of substrate pads of the package substrate via conductive connection members that are disposed on the plurality of chip pads of the semiconductor chip. A pair of first flow control structures is disposed in the first region of the package substrate. The pair of first flow control structures are disposed symmetrically on both sides along a center line passing through a center of the chip mounting region. A spacing distance between the pair of first flow control structures gradually decreases towards the chip mounting region. At least one pair of second flow control structures is disposed in the second region of the package substrate. The at least one pair of second flow control structures are disposed symmetrically on both sides of the chip mounting region. A third flow control structure is disposed in the third region of the package substrate and is arranged in line with the semiconductor chip along the center line. A molding member is on the package substrate. The molding member fills a gap between the semiconductor chip and the package substrate and covers the semiconductor chip, the pair of first flow control structures, the at least one pair of second flow control structures and the third flow control structure.

According to an example embodiment, in a method of manufacturing a semiconductor package, a package substrate is provided to include a first region, a second region, and a third region sequentially arranged from the first side portion thereof. The second region has a chip mounting region in a central region. A semiconductor chip may be mounted on a plurality of substrate pads provided in the chip mounting region of the package substrate via conductive connection members formed on chip pads. A pair of first flow control structures may be stacked on the first region of the package substrate to be disposed symmetrically on both sides of the package substrate with a center line passing through the center of the chip mounting region. At least one pair of second flow control structures may be stacked on the second region of the package substrate to be symmetrically disposed on both sides of the chip mounting region. A molding member may be formed to cover the semiconductor chip, the pair of first flow control structures and the at least one pair of second flow control structures on the substrate package and fill a gap between the semiconductor chip and the package substrate.

According to an example embodiment, a semiconductor package includes a package substrate having a first region, a second region and third region sequentially arranged from a first side portion thereof. The second region has a chip mounting region in a central region. A semiconductor chip is disposed on the chip mounting region of the package substrate. The semiconductor chip is mounted on a plurality of substrate pads of the package substrate via conductive connection members formed on a plurality of chip pads. A pair of first flow control structures is disposed in the first region of the package substrate and is disposed symmetrically on both sides along a center line passing through a center of the chip mounting region. At least one pair of second flow control structures is disposed in the second region of the package substrate and is disposed symmetrically on both sides of the chip mounting region. A molding member is on the package substrate filling a gap between the semiconductor chip and the package substrate and covering the semiconductor chip, the pair of first flow control structures and the at least one pair of second flow control structures.

The pair of first flow control structures and the at least one pair of second flow control structures may control a flow speed of molding material during a molding process in which the molding material is injected to form the molding member. During the molding process, a flow rate of a portion of the molding material passing between the pair of first flow control structures may be relatively increased. Additionally, during the molding process, a flow rate of a portion of the molding material passing between at least one pair of second flow control structures may be relatively decreased.

Accordingly, the flow speed of the molding member passing through the space between the side of the semiconductor chip and the side of the substrate (Chip to PKG Edge) decreases, and the flow speed of the molding member passing through the gap between the lower surface of the semiconductor chip and the upper surface of the substrate increases. Thus, the speed difference between the injected molding member may be reduced, thereby preventing a void trap from occurring under the flip chip.

### BRIEF DESCRIPTION OF THE DRAWINGS

FIG. 1 is a plan view illustrating a semiconductor package in accordance with an example embodiment.

FIG. 2 is a plan view illustrating the semiconductor package of FIG. 1, wherein a molding member is omitted according to an example embodiment.

FIG. 3 is a cross-sectional view taken along the line A-A′ in FIG. 1 according to an example embodiment.

FIG. 4 is a cross-sectional view taken along the line B-B′ in FIG. 1 according to an example embodiment.

FIGS. 5 to 19 are views illustrating a method of manufacturing a semiconductor package in accordance with example embodiments.

FIGS. 20 and 21 is a plan view illustrating a semiconductor package in accordance with example embodiments.

### DETAILED DESCRIPTION OF EMBODIMENTS

Hereinafter, example embodiments will be explained in detail with reference to the accompanying drawings.

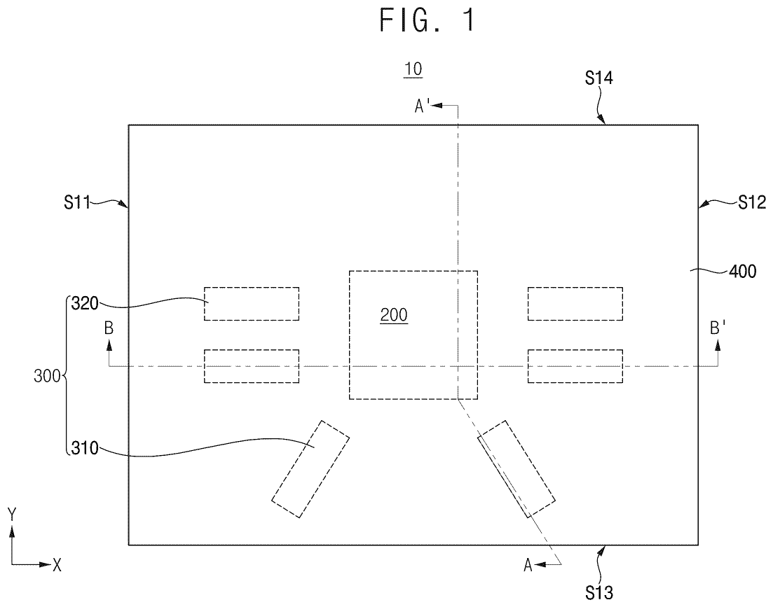

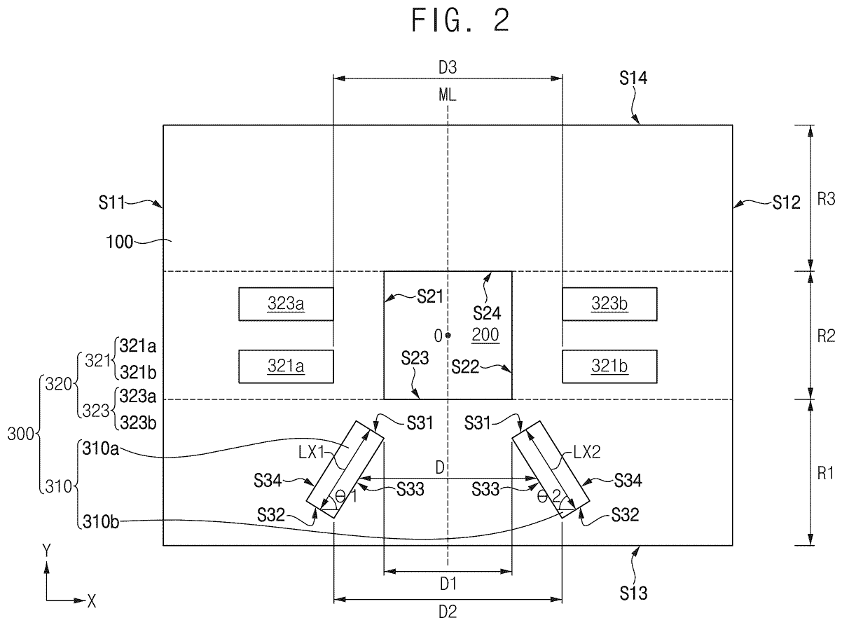

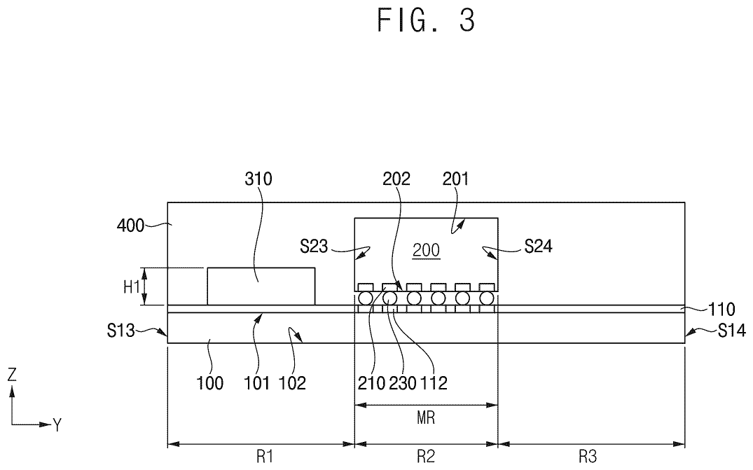

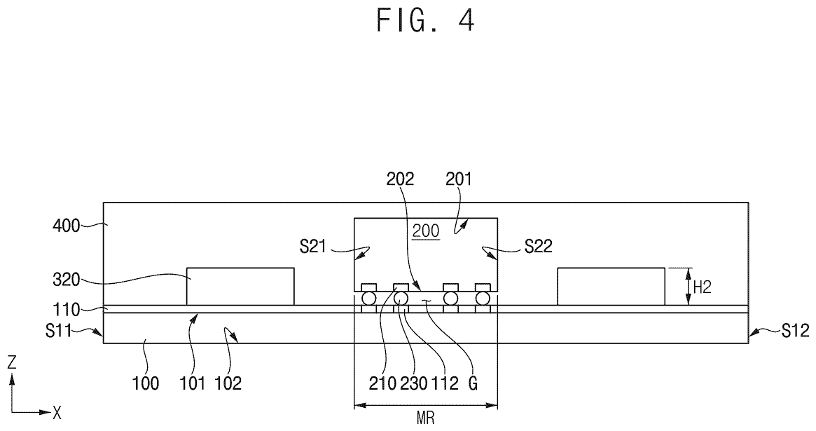

FIG. 1 is a plan view illustrating a semiconductor package in accordance with an example embodiment. FIG. 2 is a plan view illustrating the semiconductor package of FIG. 1, wherein a molding member is omitted. FIG. 3 is a cross-sectional view taken along the line A-A′ in FIG. 1. FIG. 4 is a cross-sectional view taken along the line B-B′ in FIG. 1.

Referring to FIGS. 1 to 4, a semiconductor package 10 may include a package substrate 100, at least one semiconductor chip 200, a plurality of flow control structures 300 and a molding member 400. Additionally, the semiconductor package 10 may further include a plurality of conductive connection members 230.

In an example embodiment, the package substrate 100 may extend in a first direction (e.g., the X direction) and may be a substrate having an upper surface 101 and a lower surface 102 opposite to each other (e.g., in the Z direction). For example, in an embodiment the package substrate 100 may include a printed circuit board (PCB), a flexible substrate, a tape substrate, etc. The printed circuit board may be a multilayer circuit board having vias and various circuits therein. The package substrate 100 may include internal wirings that serve as channels for electrical connection with a semiconductor chip.

The package substrate 100 may have first and second substrate side portions S11 and S12 (e.g., lateral side portions) facing each other and extending in a second direction (e.g., the Y direction) orthogonal to the first direction (e.g., the X direction). Additionally, the package substrate 100 may have third and fourth substrate side portions S13 and S14 facing each other and extending in a direction parallel to the first direction (e.g., the X direction).

The package substrate 100 may have a chip mounting region MR in a central portion thereof. A plurality of substrate pads 112 may be disposed in the chip mounting region MR. For example, in an embodiment the plurality of substrate pads 112 may be arranged as an array on the entire upper surface 101 within the chip mounting region MR of the package substrate 100. The plurality of substrate pads 112 may be respectively connected to the wirings. The wirings may extend on the upper surface 101 or inside the package substrate 100.

Although only a few substrate pads 112 are shown in the drawings, it will be understood that the number, shape, and arrangement of the substrate pads are provided as examples, and embodiments of the present inventive concept are not necessarily limited thereto. Since the wirings, including the substrate pads, are well known in the technical field for the present inventive concept, their illustration and description will be omitted.

An insulation layer 110 may be disposed on the upper surface 101 of the package substrate 100 to expose the plurality of substrate pads 112, such as an upper surface of the plurality of substrate pads 112. The insulation layer 110 may cover the entire upper surface 101 of the package substrate 100 excluding the upper surface of the plurality of substrate pads 112. For example, in an embodiment the insulation layer may include a solder resist.

As illustrated in FIG. 2, the package substrate 100 may include a first region R1, a second region R2 and a third region R3 that are sequentially arranged (e.g., in the Y direction) from the third substrate side portion S13.

For example, the first region R1 may be disposed on the upper surface 101 of the package substrate 100 to be adjacent to (e.g., directly adjacent thereto) the third substrate side portion S13. The third region R3 may be disposed on the upper surface 101 of the package substrate 100 to be adjacent to (e.g., directly adjacent thereto) the fourth substrate side portion S14. In an embodiment, the second region R2 may have the chip mounting region MR positioned in a central portion thereof (e.g., central portion in a plane defined in the X and Y directions), and the second region R2 may be disposed between the first region R1 and the third region R3 (e.g., in the Y direction). The first region R1, the second region R2, and the third region R3 may be sequentially arranged along the second direction (e.g., the Y direction). For example, in an embodiment when viewed in a plan view (e.g., in a plane defined in the X and Y directions), the first region R1, the second region R2 and the third region R3 may have a rectangular shape.

For example, in an embodiment a length of the chip mounting region MR in the second direction (e.g., the Y direction) may be equal to a length of the second region R2 in the second direction (e.g., the Y direction). For example, in an embodiment a sum of the length of the first region R1, the length of the second region R2, and the length of the third region R3 in the second direction (e.g., the Y direction) may be equal to the length of the package substrate 100 in the second direction (e.g., the Y direction). In an embodiment, the lengths of the first to third regions R1 to R3 in the first direction (e.g., the X direction) may each be equal to the length of the package substrate 100 in the first direction (e.g., the X direction).

In example embodiments, the semiconductor chip 200 may be mounted on the chip mounting region MR of the package substrate 100. The semiconductor chip 200 may be mounted on the package substrate 100 via a plurality of conductive connection members 230. In an embodiment, the semiconductor chip 200 may be disposed such that a lower surface 202 having a plurality of chip pads 210 are disposed, such as an active surface, faces the package substrate 100. In an embodiment, the plurality of chip pads 210 may be arranged as an array over the entire lower surface 202 of the semiconductor chip 200.

In an embodiment, the semiconductor chip 200 may be a rectangular shape having four sides when viewed in a plan view (e.g., in a plane defined in the X and Y directions). The semiconductor chip 200 may have a first chip side portion S21 and a second chip side portion S22 facing each other to extend in a direction parallel to the second direction (e.g., the Y direction) and spaced apart from each other in the first direction (e.g., the X direction). Additionally, the semiconductor chip 200 may have third chip side portion S23 and a fourth chip side portion S24 facing each other and extending in the first direction (e.g., the X direction) and spaced apart from each other in the second direction (e.g., the Y direction).

In an embodiment, the semiconductor chip 200 may be mounted on the package substrate 100 by a flip chip bonding method. In an embodiment, the plurality of chip pads 210 of the semiconductor chip 200 may be electrically connected to the plurality of substrate pads 112 of the package substrate 100 via a plurality of conductive bumps 230 as the conductive connection members, for example, solder bumps. A gap G may be formed between the upper surface 101 of the package substrate 100 and the lower surface 202 of the semiconductor chip 200 (e.g., in the Z direction) by the plurality of conductive bumps 230.

A distance between one side portion of the semiconductor chip 200 and one side portion of the package substrate 100 may be greater than the gap G disposed under the semiconductor chip 200. For example, a space between the first chip side portion S21 of the semiconductor chip 200 and the first substrate side portion S11 of the package substrate 100 (Chip to PKG Edge) may be greater than the gap G (Joint Gap Size).

In an example embodiment, the plurality of flow control structures 300 may include a pair of first flow control structures 310 and at least one pair of second flow control structures 320. However, embodiments of the present inventive concept are not necessarily limited thereto and the number of the first and second flow control structures 310, 320 may vary. The plurality of flow control structures 300 may be structures to control a flow of a molding material that is injected during a molding process.

The plurality of flow control structures 300 may be disposed on the package substrate 100. In an embodiment, the plurality of flow control structures 300 may be capacitors that are electrically connected to the package substrate 100. In this embodiment, the plurality of flow control structures 300 may supply current to the semiconductor chip 200 or prevent noise of a circuit. Alternatively, in an embodiment the plurality of flow control structures 300 may be stiffeners that are configured to prevent a warpage of a semiconductor package or may be dummy chips that are configured to control a flow of a molding material. For example, in an embodiment the pair of first flow control structures 310 may be capacitors that are electrically connected to the package substrate 100 and the at least one pair of second flow control structures 320 are stiffeners that are configured to prevent a warpage of the semiconductor package.

In an embodiment, the pair of first flow control structures 310 may be disposed in the first region R1 of the package substrate 100. For example, the pair of first flow control structures 310 may be disposed on the package substrate 100 to be spaced apart from the semiconductor chip 200 in the second direction (e.g., the Y direction). The pair of first flow control structures 310 may be structures that are configured to increase a flow rate of the molding material injected into a space between the pair of first flow control structures 310.

In an embodiment, the pair of first flow control structures 310 may be symmetrically arranged with respect to a center line ML passing through a center of the chip mounting region MR. The pair of first flow control structures 310 may include a first control structure 310a and a second control structure 310b. For example, each of the pair of first flow control structures 310 may include a first side portion S31 facing the first semiconductor chip 200, a second side portion S32 extending parallel to the first side portion S31 and facing the first side portion S31, a third side portion S33 extending perpendicular to the first side portion S31 and a fourth side portion S34 extending parallel to the third side portion S33 and facing the third side portion S33.

In an embodiment, each of the third side portions S33 of the pair of first flow control structures 310 may be disposed towards the center line ML to face each other such that the pair of first flow control structures 310 are symmetrically disposed with respect to the semiconductor chip 200.

The pair of first flow control structures 310 may have a first height H1 (e.g., length in the Z direction) from the upper surface 101 of the package substrate 100. For example, the first height H1 may be greater than a distance (e.g., in the Z direction) from the upper surface 101 of the package substrate 100 to a lower surface 202 of the semiconductor chip 200, and, the first height H1 may be less than a distance (e.g., in the Z direction) from the upper surface 101 of the package substrate 100 to an upper surface 201 of the semiconductor chip 200.

In an embodiment, a first long axis LX1 of the first control structure 310a and a second long axis LX2 of the second control structure 310b may be disposed towards the chip mounting region MR, e.g., the center O of the chip mounting region MR. For example, the first long axis LX1 and the second long axis LX2 may be perpendicular to the first side portion S31 and may be disposed towards the center O of the chip mounting region MR.

A spacing distance D (e.g., length in the X direction) between the pair of first flow control structures 310 may gradually decrease towards the chip mounting region MR. For example, the spacing distance D between the third side portion S33 of the first control structure 310a and the third side portion S33 of the second control structure 310b may decrease as the first control structure 310a and the second control structure 310b approach the gap G provided under the semiconductor chip 200. For example, the spacing distance between the third side portions closer to the gap G provided under the semiconductor chip 200 may be a first spacing distance D1. A spacing distance between the third side portions farther from the gap G provided under the semiconductor chip 200 may be a second spacing distance D2. The first spacing distance D1 may be less than the second spacing distance D2.

For example, in an embodiment the first spacing distance D1 may be less than or equal to the length of the third chip side portion S23 of the semiconductor chip 200, and the second spacing distance D2 may be greater than the length of the third chip side portion S23 of the semiconductor chip 200. However, embodiments of the present inventive concept are not necessarily limited thereto. For example, in an embodiment the first spacing distance D1 and the second spacing distance D2 may be less than or greater than the length of the third chip side portion S23 of the semiconductor chip 200.

The long axes L1 and L2 of the pair of first flow control structures 310 may be disposed to have a predetermined angle with respect to the first direction (e.g., the X direction). For example, the first long axis LX1 of the first control structure 310a may have a first angle θ1 with respect to an extension line parallel to the first direction (e.g., the X direction). The second long axis LX2 of the second control structure 310b may have a second angle θ2 with respect to an extension line parallel to the first direction (e.g., the X direction). In an embodiment, the first angle θ1 and the second angle θ2 may be an acute angle within a range of 0° to 90°. For example, in an embodiment the first angle θ1 and the second angle θ2 may be identical to each other. Alternatively, in some embodiments the first angle θ1 and the second angle θ2 may be different from each other.

In example embodiments, the at least one pair of second flow control structures 320 may be disposed in the second region R2 of the package substrate 100. For example, the at least one pair of second flow control structures 320 may be disposed on the package substrate 100 to be spaced apart from the semiconductor chip 200 in the first direction (e.g., the X direction). The semiconductor chip 200 may be disposed between the at least one pair of second flow control structures 320. The least one pair of second flow control structures 320 may be structures that are configured to decrease a flow speed of the molding material injected on the second region R2.

The at least one pair of second flow control structures 320 may have a second height H2 (e.g., length in the Z direction) from the upper surface 101 of the package substrate 100. For example, in an embodiment the second height H2 may be greater than a distance (e.g., in the Z direction) from the upper surface 101 of the package substrate 100 to the lower surface 202 of the semiconductor chip 200, and the second height H2 may be less than a distance (e.g., in the Z direction) from the upper surface 101 of the package substrate 100 to the upper surface 201 of the semiconductor chip 200.

In an embodiment, the at least one pair of second flow control structures 320 may include a first pair of second flow control structures 321 and a second pair of second flow control structures 323. The first pair of second flow control structures 321 may include a third control structure 321a and a fourth control structure 321b, and the second pair of second flow control structures 323 may include a fifth control structure 323a and a sixth control structure 323b.

In an embodiment, the at least one pair of second flow control structures 320 may be disposed symmetrically on the package substrate 100 such that the semiconductor chip 200 is disposed between the at least one pair of second flow control structures 320 (e.g., in the X direction). For example, in an embodiment the at least one pair of second flow control structures 320 may be disposed symmetrically with respect to the center line ML of the chip mounting region MR. For example, the third control structure 321a may be disposed in an area adjacent to the first substrate side portion S11 of the package substrate 100. The fourth control structure 321b may be disposed in an area adjacent to the second substrate side S12 of the package substrate 100 such that the fourth control structure 321b is symmetrical with the third control structure 321a about the center line ML.

In an embodiment, a spacing distance between the at least one pair of second flow control structures 320 may be greater than the spacing distance between the pair of first flow control structures 310. For example, the spacing distance between at least one pair of the second flow control structures 320 may be a third spacing distance D3. The first spacing distance D1 between the pair of first flow control structures 310 may be less than the third spacing distance D3 between the at least one pair of second flow control structures 320. In an embodiment, the second spacing distance D2 between the pair of first flow control structures 310 may be less than or equal to the third spacing distance D3 between the at least one pair of second flow control structures 320, respectively.

The at least one pair of second flow control structures 320 may be disposed along both side portions of the package substrate 100 that extend parallel to the second direction (e.g., the Y direction) such that the semiconductor chip 200 is disposed between the at least one pair of second flow control structures 320 (e.g., in the X direction). For example, the third control structure 321a and the fifth control structure 323a may be sequentially arranged (e.g., in the Y direction) along the first substrate side portion S11. The fourth control structure 321b and the sixth control structure 323b may be sequentially arranged (e.g., in the Y direction) along the second substrate side portion S12.

The at least one pair of second flow control structures 320 may be disposed in parallel with the first direction (e.g., the X direction). For example, each of at least one pair of second flow control structures 320 may have a rectangular shape having four side portions. At least one of the four side portions may be disposed in parallel with the third substrate side portion S13 of the package substrate 100 and the fourth substrate side portion S14 of the package substrate 100.

However, embodiments of the present inventive concept are not necessarily limited thereto and the shape, size, arrangement, number, and the like of the first and second flow control structures 310, 320 may vary, such as according to the flow rate of the molding material injected during the molding process. Although only a few flow control structures are shown in the drawings, embodiments of the present inventive concept are not necessarily limited thereto and the number, shape, and arrangement of the flow control structures may vary.

In example embodiments, the molding member 400 may cover the semiconductor chip 200 and the plurality of flow control structures 300 on the upper surface 101 of the package substrate 100. In an embodiment, the molding member may include a thermosetting resin, for example, an epoxy mold compound (EMC).

A portion of the molding member 400 may fill the gap G between the lower surface 202 of the semiconductor chip 200 and the upper surface 101 of the package substrate 100. The portion of the molding member 400 may serve as an underfill member under the semiconductor chip 200 that is mounted by the flip chip method.

As mentioned above, the semiconductor package may include the semiconductor chip 200 mounted on the chip mounting region MR of the package substrate 100 and having the gap G formed between the upper surface 101 of the package substrate 100, the pair of first flow control structures 310 provided on the upper surface 101 of the package substrate 100, the at least one pair of second flow control structures 320 and the molding member 400 filling the gap G under the semiconductor chip 200.

The pair of first flow control structures 310 and the at least one pair of second flow control structures 320 may control a flow speed of a molding material during a molding process in which the molding material is injected to form the molding member. During the molding process, a flow rate of a portion of the molding material passing between the pair of first flow control structures may be relatively increased. Additionally, during the molding process, a flow rate of a portion of the molding material passing between at least one pair of second flow control structures may be relatively decreased.

Accordingly, the flow speed of the molding member 400 passing through the space between the side of the semiconductor chip 200 and the side of the package substrate 100 (Chip to PKG Edge) may decrease, and the flow speed of the molding member 400 passing through the gap G between the lower surface of the semiconductor chip 200 and the upper surface of the package substrate 100 may increase. Thus, the speed difference between the injected molding member 400 may be reduced, thereby preventing a void trap from occurring under the flip chip bonding method.

Hereinafter, a method of manufacturing the semiconductor package of FIG. 1 will be described.

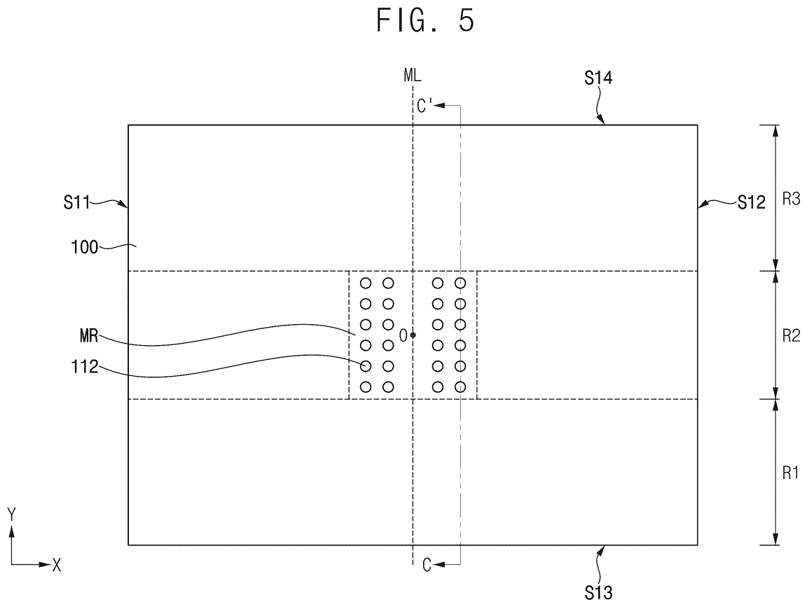

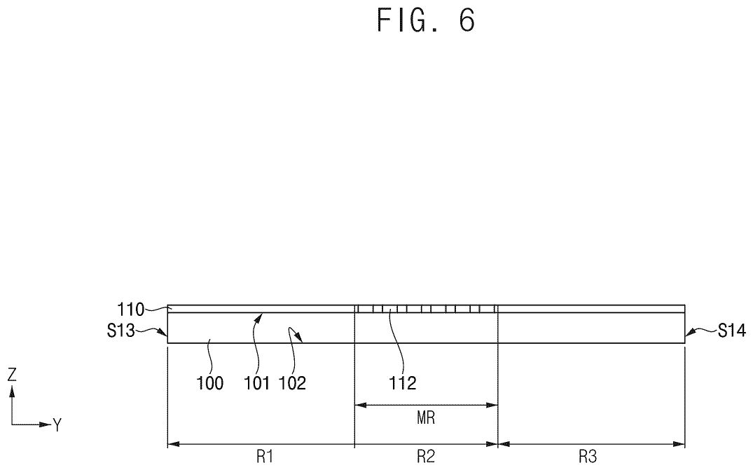

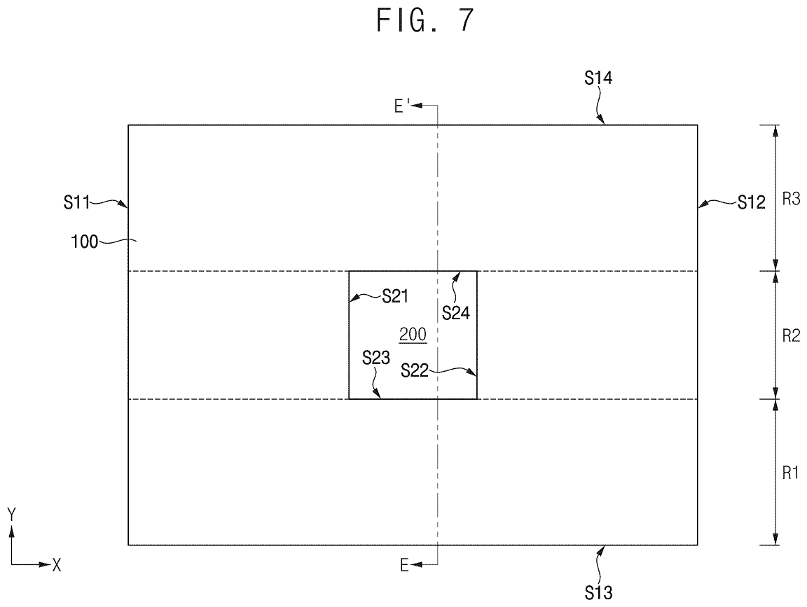

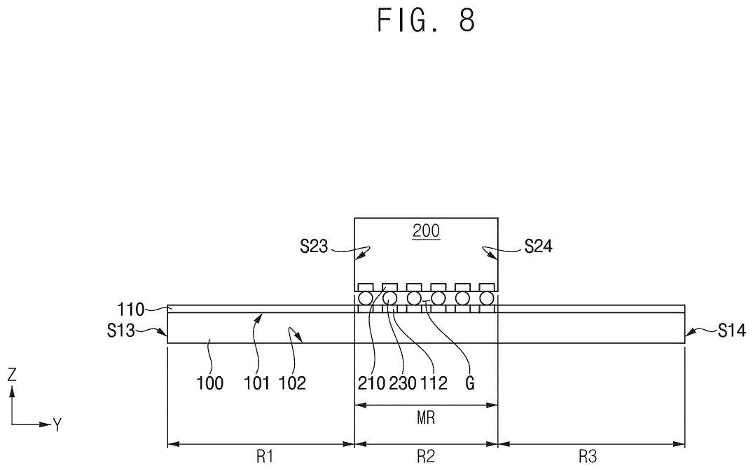

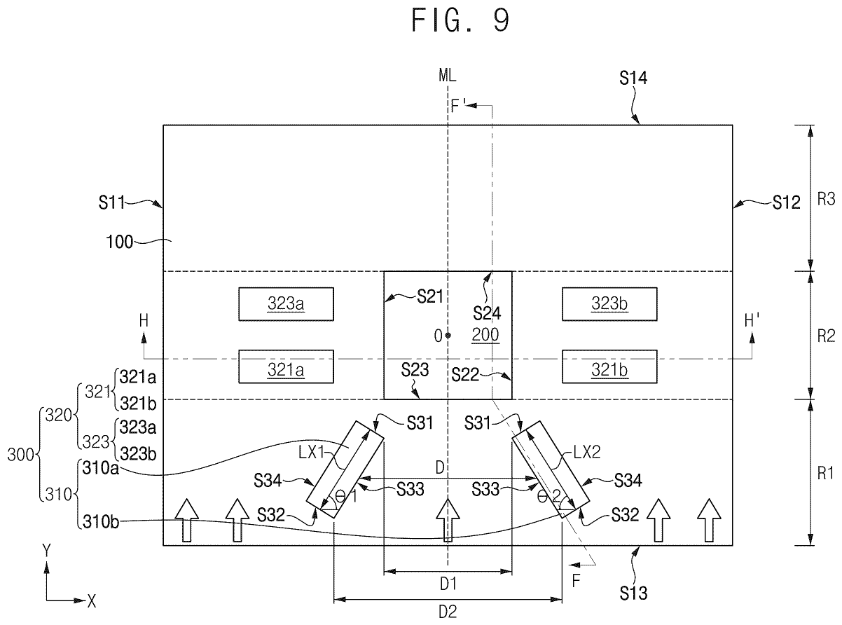

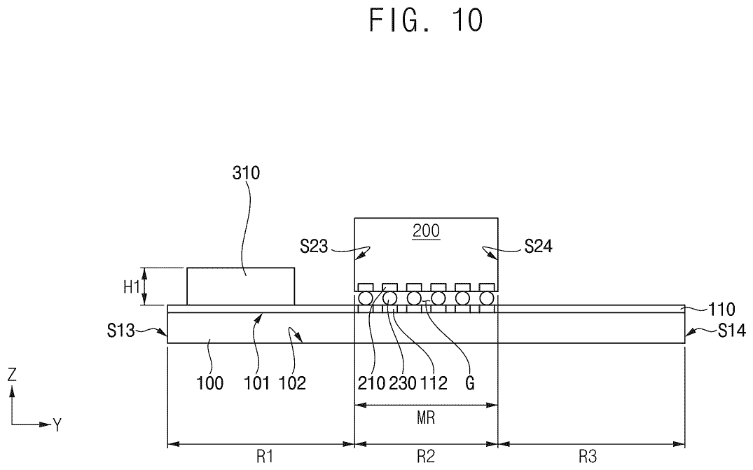

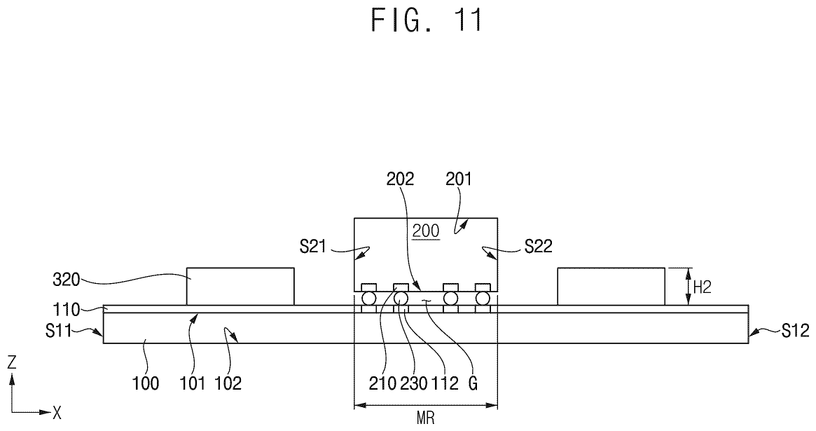

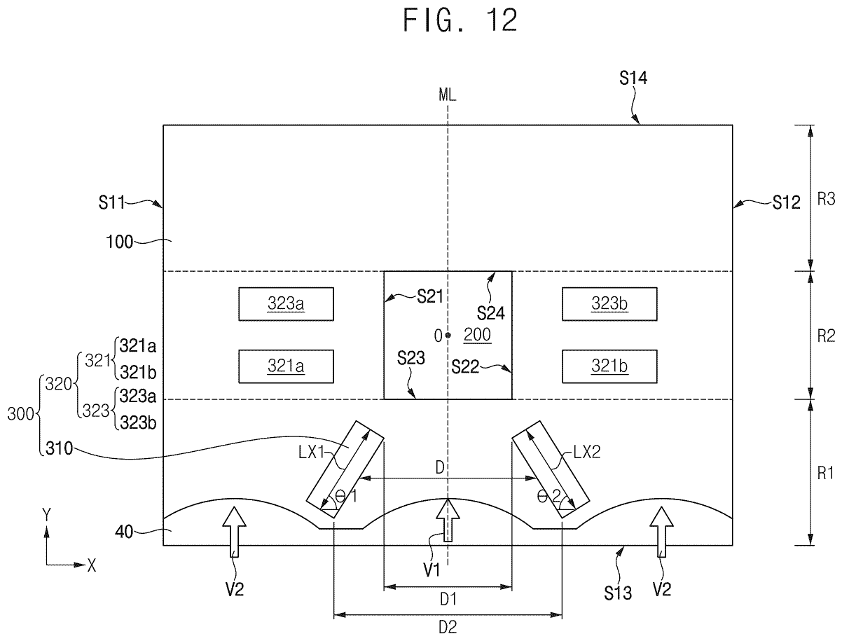

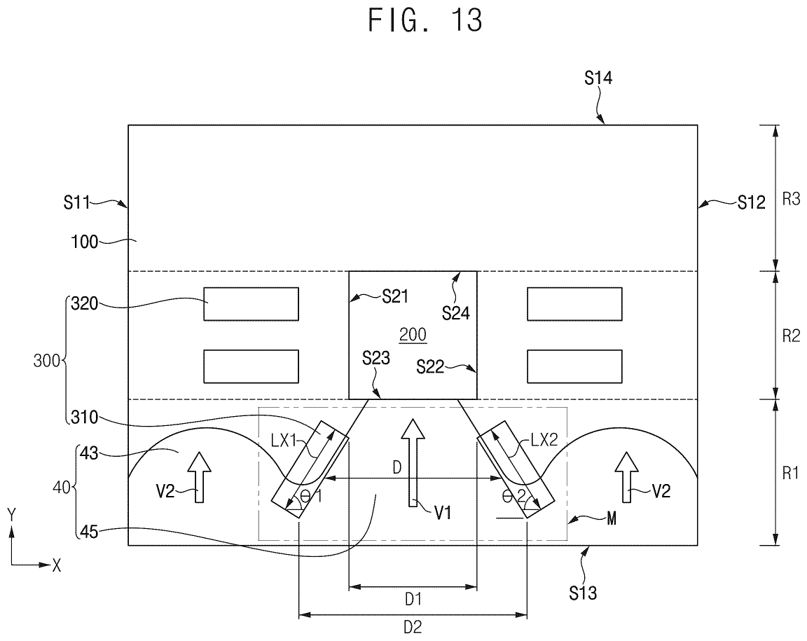

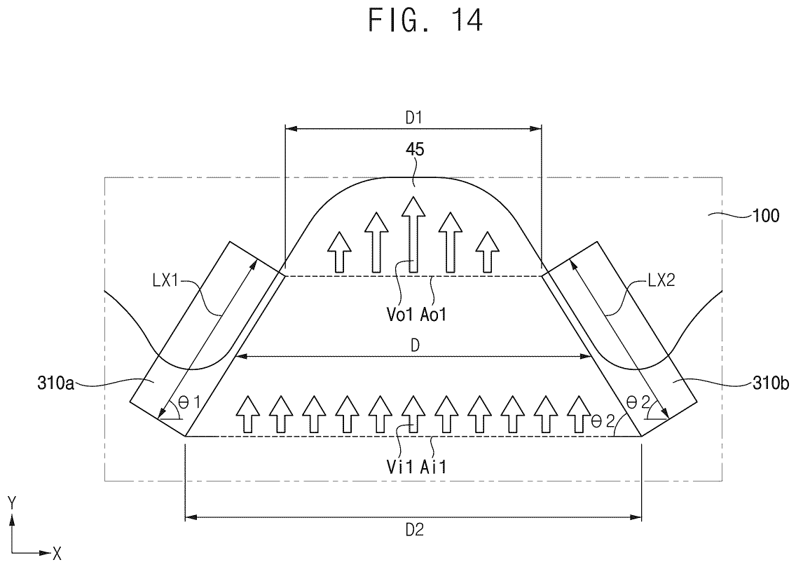

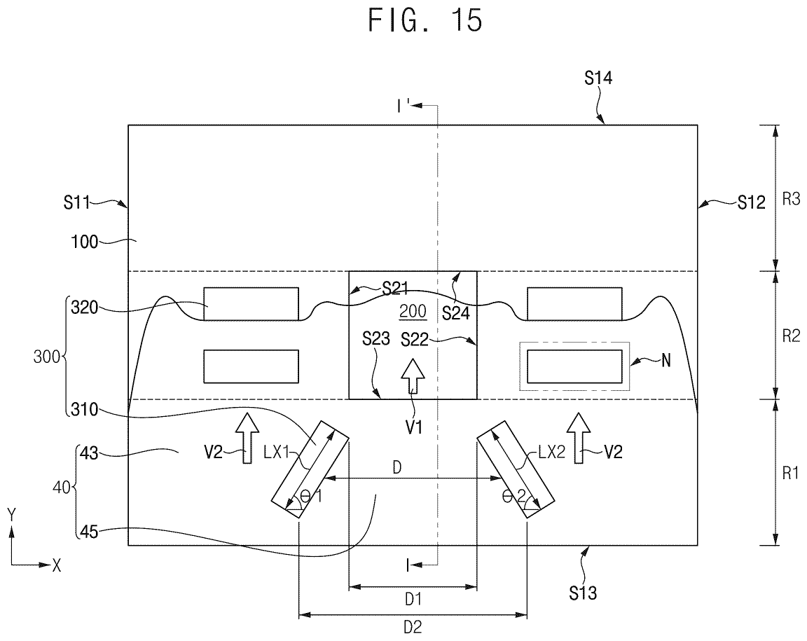

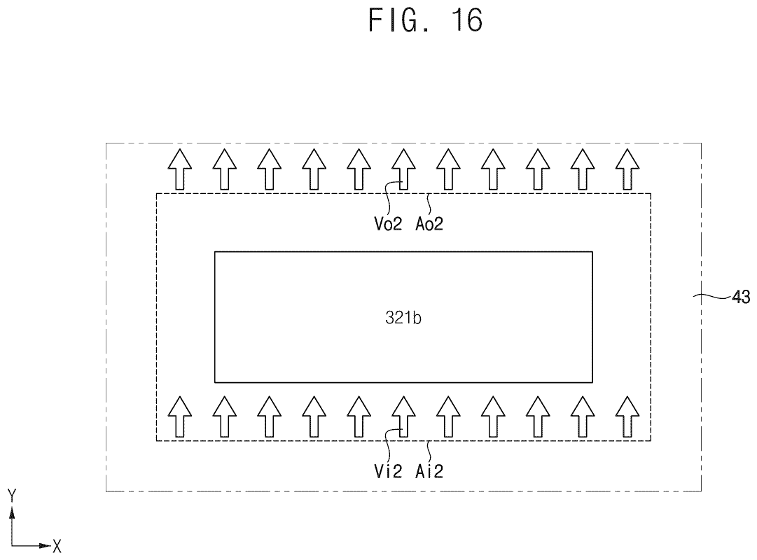

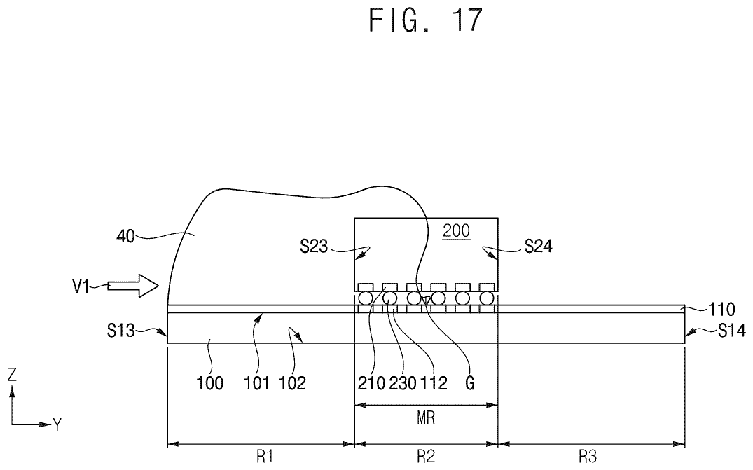

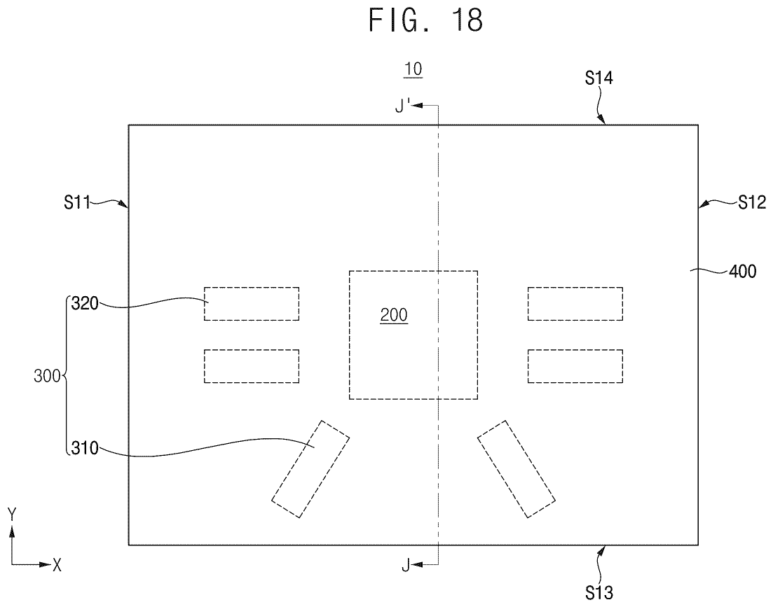

FIGS. 5 to 19 are views illustrating a method of manufacturing a semiconductor package in accordance with example embodiments. FIG. 5, FIG. 7, FIG. 9, FIG. 12, FIG. 13, FIG. 15 and FIG. 18 are plan views illustrating a method of manufacturing a semiconductor package in accordance with example embodiments. FIG. 6 is a cross-sectional view taken along the line C-C′ in FIG. 5. FIG. 8 is a cross-sectional view taken along the line D-D′ in FIG. 7. FIG. 10 is a cross-sectional view taken along the line F-F′ in FIG. 9. FIG. 11 is a cross-sectional view taken along the line H-H′ in FIG. 9. FIG. 14 is an enlarged plan view illustrating a portion ‘M’ in FIG. 13. FIG. 16 is an enlarged plan view illustrating a portion ‘N’ in FIG. 15. FIG. 17 is a cross-sectional view taken along the line I-I′ in FIG. 15. FIGS. 12 to 16 are plan views illustrating a flow of a molding material during a molding process

Referring to FIGS. 5 and 6, a package substrate 100 having a chip mounting region MR may be provided.

In example embodiments, the package substrate 100 may extend in a first direction (e.g., the X direction) and may be a substrate having an upper surface 101 and a lower surface 102 opposite to each other (e.g., in the Z direction). For example, in an embodiment the package substrate 100 may include a printed circuit board (PCB), a flexible substrate, a tape substrate, etc. The printed circuit board may be a multilayer circuit board having vias and various circuits therein. The package substrate 100 may include internal wirings that serve as channels for electrical connection with a semiconductor chip.

The package substrate 100 may have first and second substrate side portions S11 and S12 extending in a second direction (e.g., the Y direction) orthogonal to the first direction (e.g., the X direction) and facing each other. Additionally, the package substrate 100 may have third and fourth substrate side portions S13 and S14 extending in a direction parallel with the first direction (e.g., the X direction) and facing each other.

The package substrate 100 may have the chip mounting region MR in a central portion thereof (e.g., a central portion in a plane defined in the X and Y directions). A plurality of substrate pads 112 may be provided in the chip mounting region MR. For example, in an embodiment the plurality of substrate pads 112 may be arranged as an array on the entire upper surface 101 within the chip mounting region MR of the package substrate 100. The plurality of substrate pads 112 may be respectively connected to the wirings. The wirings may extend on the upper surface 101 or inside the package substrate 100.

Although only a few substrate pads are shown in the drawings, it will be understood that the number, shape, and arrangement of the substrate pads are provided as examples, and the embodiments of the present inventive concept are not necessarily limited thereto. Since the wirings, including the substrate pads, are well known in the technical field for the present inventive concept, their illustration and description will be omitted.

An insulation layer 110 may be formed on the upper surface 101 of the package substrate 100 to expose the plurality of substrate pads 112, such as the upper surfaces of the plurality of substrate pads 112. The insulation layer 110 may cover the entire upper surface 101 of the package substrate 100 excluding the upper surface of the plurality of substrate pads 112. For example, in an embodiment the insulation layer may include a solder resist.

As illustrated in FIG. 5, the package substrate 100 may include a first region R1, a second region R2 and a third region R3 that are sequentially arranged from the third substrate side portion S13 towards the fourth substrate side portion S14 (e.g., in the Y direction).

For example, the first region R1 may be adjacent to (e.g., immediately adjacent thereto) the third substrate side portion S13. The third region R3 may be adjacent to (e.g., immediately adjacent thereto) the fourth substrate side portion S14. The second region R2 may have the chip mounting region MR in a central portion thereof, and the second region R2 may be disposed between the first region R1 and the third region R3 (e.g., in the Y direction). The first region R1, the second region R2, and the third region R3 may be sequentially arranged along the second direction (e.g., the Y direction). For example, in an embodiment when viewed in a plan view, the first region R1, the second region R2 and the third region R3 may have a rectangular shape.

For example, a length of the chip mounting region MR in the second direction (e.g., the Y direction) may be equal to a length of the second region R2 in the second direction (e.g., the Y direction). For example, a sum of the lengths of the first region R1, the length of the second region R2, and the length of the third region R3 in the second direction (e.g., the Y direction) may be equal to the length of the package substrate 100 in the second direction (e.g., the Y direction).

Referring to FIGS. 7 and 8, a semiconductor chip 200 may be mounted on the chip mounting region MR of the package substrate 100.

In example embodiments, the semiconductor chip 200 may be mounted on the chip mounting region MR of the package substrate 100. In an embodiment, the semiconductor chip 200 may be mounted on the package substrate 100 via a plurality of conductive connection members 230. The semiconductor chip 200 may be disposed such that a lower surface 202 having a plurality of chip pads 210 formed thereon, such as an active surface, faces the package substrate 100. The plurality of chip pads 210 may be arranged as an array over the entire lower surface 202 of the semiconductor chip 200.

In an embodiment, the semiconductor chip 200 may be a rectangular shape having four sides when viewed in a plan view. The semiconductor chip 200 may have a first chip side portion S21 and a second chip side portion S22 extending in a direction parallel to the second direction (e.g., the Y direction) and facing each other. Additionally, the semiconductor chip 200 may have a third chip side portion S23 and a fourth chip side portion S24 extending in the first direction (e.g., the X direction) and facing each other.

In an embodiment, the semiconductor chip 200 may be mounted on the package substrate 100 by a flip chip bonding method. The plurality of chip pads 210 of the semiconductor chip 200 may be electrically connected to the plurality of substrate pads 112 of the package substrate 100 via a plurality of conductive bumps 230 as the conductive connection members, such as solder bumps. A gap G may be formed (e.g., in the Z direction) between the upper surface 101 of the package substrate 100 and the lower surface 202 of the semiconductor chip 200 by the plurality of conductive bumps 230.

A distance between one side portion of the semiconductor chip 200 and one side portion of the package substrate 100 may be greater than the gap G disposed under the semiconductor chip 200. For example, a space between the first chip side portion S21 of the semiconductor chip 200 and the first substrate side portion S11 of the package substrate 100 (Chip to PKG Edge) may be greater than the gap G (Joint Gap Size).

Referring to FIGS. 9 to 11, a plurality of flow control structures may be provided on the package substrate 100.

In an embodiment, the plurality of flow control structures 300 may include a pair of first flow control structures 310 and at least one pair of second flow control structures 320. The plurality of flow control structures 300 may be structures that are configured to control a flow of a molding material to be injected during a molding process.

The plurality of flow control structures 300 may be disposed on the package substrate 100. In an embodiment, the plurality of flow control structures 300 may be capacitors that are mounted to be electrically connected to the package substrate 100. In this embodiment, the plurality of flow control structures 300 may supply current to the semiconductor chip 200 or prevent noise of a circuit. Alternatively, the plurality of flow control structures 300 may be stiffeners that are configured to prevent a warpage of a semiconductor package or may be dummy chips that are configured to control a flow of a molding material.

In example embodiments, the pair of first flow control structures 310 may be disposed in the first region R1 of the package substrate 100. For example, the pair of first flow control structures 310 may be disposed on the package substrate 100 to be spaced apart from the semiconductor chip 200 in the second direction (e.g., the Y direction). The pair of first flow control structures 310 may be structures that are configured to increase a flow rate of the molding material injected into a space between the pair of first flow control structures 310.

In an embodiment, the pair of first flow control structures 310 may be symmetrically arranged with respect to a center line ML passing through a center of the chip mounting region MR. In an embodiment, the pair of first flow control structures 310 may include a first control structure 310a and a second control structure 310b. For example, in an embodiment each of the pair of first flow control structures 310 may include a first side portion S31 facing the first semiconductor chip 200, a second side portion S32 parallel to the first side portion S31 to face the first side portion S31, a third side portion S33 perpendicular to the first side portion S31, and a fourth side portion S34 parallel to the third side portion S33 to face the third side portion S33.

In an embodiment, each of the third side portions S33 of the pair of first flow control structures 310 may be disposed towards the center line ML to face each other such that the pair of first flow control structures 310 are symmetrically disposed with respect to the semiconductor chip 200.

The pair of first flow control structures 310 may have a first height H1 (e.g., length in the Z direction) from the upper surface 101 of the package substrate 100. For example, the first height H1 may be greater than a distance from the upper surface 101 of the package substrate 100 to the lower surface 202 of the semiconductor chip 200, and, the first height H1 may be less than a distance from the upper surface 101 of the package substrate 100 to an upper surface 201 of the semiconductor chip 200.

A first long axis LX1 of the first control structure 310a and a second long axis LX2 of the second control structure 310b may be disposed towards the chip mounting region MR, e.g., the center O of the chip mounting region MR. For example, the first long axis LX1 and the second long axis LX may be perpendicular to the first side portion S31 and may be disposed towards the center O of the chip mounting region MR.

A spacing distance D (e.g., length in the X direction) between the pair of first flow control structures 310 may gradually decrease towards the chip mounting region MR. For example, the spacing distance D between the third side portion S33 of the first control structure 310a and the third side portion S33 of the second control structure 310b may decrease as the first control structure 310a and the second control structure 310b approach the gap G provided under the semiconductor chip 200. For example, the spacing distance between the third side portions closer to the gap G provided under the semiconductor chip 200 may be a first spacing distance D1. A spacing distance between the third side portions farther from the gap G provided under the semiconductor chip 200 may be a second spacing distance D2. The first spacing distance D1 may be less than the second spacing distance D2.

For example, in an embodiment the first spacing distance D1 may be less than or equal to the length of the third chip side portion S23 of the semiconductor chip 200, and the second spacing distance D2 may be greater than the length of the third chip side portion S23 of the semiconductor chip 200. Alternatively, the first spacing distance D1 and the second spacing distance D2 may be less than or greater than the length of the third chip side portion S23 of the semiconductor chip 200.

The long axes L1 and L2 of the pair of first flow control structures 310 may be disposed to have a predetermined angle with respect to the second direction (e.g., the Y direction). For example, the first long axis LX1 of the first control structure 310a may have a first angle θ1 with respect to an extension line parallel to the first direction (e.g., the X direction). The second long axis LX2 of the second control structure 310b may have a second angle θ2 with respect to an extension line parallel to the first direction (e.g., the X direction). The first angle θ1 and the second angle θ2 may be an acute angle within a range of 0° to 90°. For example, in an embodiment the first angle θ1 and the second angle θ2 may be identical to each other. Alternatively, the first angle θ1 and the second angle θ2 may be different from each other.

In example embodiments, the at least one pair of second flow control structures 320 may be disposed in the second region R2 of the package substrate 100. For example, the at least one pair of second flow control structures 320 may be disposed on the package substrate 100 to be spaced apart from the semiconductor chip 200 in the first direction (e.g., the X direction). The semiconductor chip 200 may be disposed between the at least one pair of second flow control structures 320 (e.g., in the X direction). The at least one pair of second flow control structures 320 may be structures that are configured to decrease a flow rate of the molding material injected on the second region R2.

The at least one pair of second flow control structures 320 may have a second height H2 (e.g., length in the Z direction) from the upper surface 101 of the package substrate 100. For example, the second height H2 may be greater than a distance (e.g., in the Z direction) from the upper surface 101 of the package substrate 100 to the lower surface 202 of the semiconductor chip 200, and the second height H2 may be less than a distance (e.g., in the Z direction) from the upper surface 101 of the package substrate 100 to the upper surface 201 of the semiconductor chip 200.

In an embodiment, the at least one pair of second flow control structures 320 may include a first pair of second flow control structures 321 and a second pair of second flow control structures 323. The first pair of second flow control structures 321 may include a third control structure 321a and a fourth control structure 321b, and the second pair of second flow control structures 323 may include a fifth control structure 323a and a sixth control structure 323b.

In an embodiment, the at least one pair of second flow control structures 320 may be disposed symmetrically on the package substrate 100 such that the semiconductor chip 200 is provided between the at least one pair of second flow control structures 320. For example, the at least one pair of second flow control structures 320 may be disposed symmetrically with respect to the center line ML of the chip mounting region MR. For example, the third control structure 321a may be disposed in an area adjacent to the first substrate side portion S11 of the package substrate 100. The fourth control structure 321b may be disposed in an area adjacent to the second substrate side S12 of the package substrate 100 such that the fourth control structure 321b is symmetrical with the third control structure 321a about the center line ML.

In an embodiment, a spacing distance (e.g., in the X direction) between the at least one pair of second flow control structures 320 may be greater than the spacing distance (e.g., in the X direction) between the pair of first flow control structures 310. For example, the spacing distance between the at least one pair of the second flow control structures 320 may be a third spacing distance D3. The second spacing distance D2 between the pair of first flow control structures 310 may be less than or equal to the third spacing distance D3 between the at least one pair of second flow control structures 320. The first spacing distance D1 between the pair of first flow control structures 310 may be less than the third spacing distance D3 between the at least one pair of second flow control structures 320.

The at least one pair of second flow control structures 320 may be disposed along both side portions of the package substrate 100 extending parallel to the second direction (e.g., the Y direction) such that the semiconductor chip 200 is disposed between the at least one pair of second flow control structures 320 (e.g., in the X direction). For example, the third control structure 321a and the fifth control structure 323a may be sequentially arranged (e.g., in the Y direction) along the first substrate side portion S11. The fourth control structure 321b and the sixth control structure 323b may be sequentially arranged (e.g., in the Y direction) along the second substrate side portion S12.

The at least one pair of second flow control structures 320 may be disposed in parallel with the first direction (e.g., the X direction). For example, each of at least one pair of second flow control structures 320 may have a rectangular shape having four side portions. At least one of the four side portions may be disposed in parallel with the third substrate side portion S13 of the package substrate 100.

However, embodiments of the present inventive concept are not necessarily limited thereto and the shape, size, arrangement, number, and the like of the first and second flow control structures 310, 320 may vary, such as according to the flow rate of the molding material injected during the molding process. Although only a few flow control structures are shown in the drawings, the number, shape, and arrangement of the flow control structures are not necessarily limited thereto.

In an embodiment, a molding member 400 may then be formed on the package substrate 100 to complete the semiconductor package 10 of FIG. 1.

Referring to FIGS. 12 to 19, the molding member 400 may be formed on the upper surface 101 of the package substrate 100 to cover the semiconductor chip 200 and the plurality of flow control structures 300. In an embodiment, the molding member may include a thermosetting resin, for example, an epoxy mold compound (EMC). In an embodiment, a transfer molding process in which an epoxy material is melted as a gel state and then a constant pressure is applied to move the epoxy material through a plurality of narrow passages in a cavity of a mold may be performed to form the molding member.

The molding material 40 may be injected on the package substrate 100 in a constant direction from one side of the package substrate 100 in the cavity. For example, the molding material 40 may be injected from the third substrate side S13 of the package substrate 100 along the second direction (e.g., the Y direction) parallel to the center line ML of the package substrate 100. The molding material 40 may include a central molding portion 45 injected between the pair of first flow control structures 310 and an outer molding portion 43 injected towards at least one pair of second flow control structures 320. The outer molding portion 43 may be a molding portion that does not include the center molding portion 45.

FIGS. 12 to 17 are views illustrating a change of a flow speed of the molding material 40 from a first time period T1 to a third time period T3 during the molding process. FIG. 12 is a plan view illustrating a flow speed of the molding material 40 in the first time period T1. The first time period T1 may be a time after the molding process starts but before the molding material 40 directly contacts the pair of first flow control structures 310. FIGS. 13 and 14 are plan views illustrating a flow speed of the molding material 40 in the second time period T2. The second time period T2 may be a time after the molding material 40 directly contacts the pair of first flow control structures 310 and before the molding material 40 directly contacts the at least one pair of second flow control structures 320. FIGS. 15 to 17 are views illustrating a flow speed of the molding material 40 in the third time period T3. The third time period T3 may be a time after the molding material 40 directly contacts the at least one pair of second flow control structures 320.

Referring to FIG. 12, the molding material 40 may have a constant speed during the first time period T1. For example, before the molding material 40 directly contacts the plurality of flow control structures 300, a first flow speed V1 of the central molding portion 45 may be equal to a second flow speed V2 of the outer molding portion 43.

Referring to FIGS. 13 and 14, during the second time period T2, the first flow speed V1 of the central molding portion 45 may increase, and the second flow speed V2 of the outer molding portion 43 may remain constant. For example, the first flow speed V1 may increase as a molding material passes through the pair of first flow control structures 310. For example, the central molding portion 45 may be injected into the gap G under the semiconductor chip 200 through the pair of first flow control structures 310.

Referring to FIG. 14, the pair of first flow control structures 310 may serve as a nozzle. A region where the central molding portion 45 enters between the pair of first flow control structures 310 may be a first inlet region Ai1. When the central molding portion 45 passes through the first inlet area Ai1, the flow speed of the central molding portion 45 may be a first inlet speed Vi1. A region where the central molding portion 45 is discharged from the pair of first flow control structures 310 may be a first outlet region Ao1. When the central molding portion 45 passes through the first outlet area Ao1, the flow speed of the central molding portion 45 may be a first outlet speed Vo1.

An area of the first outlet region Ao1 may be less than an area of the first inlet region Ai1. For example, heights of the first inlet region Ai1 and the first outlet region Ao1 may be the same as the first height H1 of a pair of first flow control structures 310. A width of the first inlet region Ai1 may be the second spacing distance D2 between the pair of the first flow control structures 310. In addition, a width of the first outlet region Ao1 may be the first spacing distance D1 between the pair of first flow control structures 310. The first spacing distance D1 of the pair of first flow control structures 310 may be less than the second spacing distance D2 of the pair of first flow control structures 310.

Accordingly, since the area of the first inlet region Ai1 is greater than the area of the first outlet region Ao1, the first outlet speed Vo1 may be greater than the first inlet speed Vi1.

When the central molding portion 45 passes between the pair of first flow control structures 310, the first flow speed V1 of the central molding portion 45 may be increased. A change of the first flow speed V1 of the central molding portion 45 passing between the pair of first flow control structures 310 may be expressed by a following equation (1).

$$Vo 1 = \frac{Ai 1}{Ao 1} * Vi 1 \qquad 〈 Equation ( 1 ) 〉$$

in which Ai1 is the area of the first inlet region Ai1 where a flow enters, and Vi1 is the speed of the first inlet velocity Vi1 passing through the first inlet region Ai1, and Ao1 is the area of the first outlet region Ao1 where a flow comes out, and Vo1 is the speed of the first outlet velocity Vo1 passing through the first outlet region Ao1.

Referring to FIGS. 15 to 17, the first flow speed V1 of the central molding portion 45 and the second flow speed V2 of the outer molding portion 43 may be reduced during the third time period T3, so that the first flow speed V1 and the second flow speed V2 may be the same or similar to each other.

The first flow speed V1 of the central molding portion 45 may be decreased. For example, the central molding portion 45 may flow between the plurality of second flow control structures 320 and then may cover the semiconductor chip 200. A portion of the central molding portion 45 may fill the gap G provided under the semiconductor chip 200. The first flow speed V1 of the central molding portion 45 may be reduced because the gap G provided under the semiconductor chip 200 is smaller than a space between a side of the semiconductor chip and a side of the package substrate (Chip to PKG Edge).

Referring to FIGS. 15 and 16, the second flow speed V2 of the outer molding portion 43 may decrease as the outer molding portion 43 passes through the at least one pair of second flow control structures 320. For example, in an embodiment the at least one pair of second flow control structures 320 may serve as a resistor to reduce the second flow speed V2.

For example, the outer molding portion 43 may be injected towards the fourth substrate side portion S14 of the package substrate 100 to be in direct contact with the at least one pair of second flow control structures 320.

Referring to FIG. 16, a second inlet region Ai2 may be a region where the outer molding portion 45 is injected toward the fourth control structure 321b. A second inlet speed Vi2 may be a flow speed of the outer molding portion 43 when the outer molding portion 43 passes through the second inlet region Ai2. A second outlet region Ao2 may be a region where the outer molding portion 45 is discharged from the fourth control structure 321b. A second outlet speed Vo2 may be a flow speed of the outer molding portion 43 when the outer molding portion 43 passes through the second outlet region Ao2.

Since the outer molding portion 45 moves while covering the entire fourth control structure 321b, an area of the second inlet region Ai2 and an area of the second outlet region Ao2 may be the same.

The outer molding portion 45 may flow from the second inlet region Ai2 to the second outlet region Ao2 while being in direct contact with the fourth control structure 321b. Since the fourth control structure 321b serves as a resistor for preventing a flow of the outer molding portion 45, the second outlet speed Vo2 may be less than the second inlet speed Vi2.

The outer molding portion 43 may pass through the at least one pair of second flow control structures 320 to reduce the second flow speed V2 of the outer molding portion 43. A change of the flow speed of the outer molding portion 43 passing through the at least one pair of second flow control structures 320 may be expressed by a following equation (2).

$$Vo 2 = \sqrt{{( Vi 2 )}^{2} - \frac{R}{ρ * A}} \qquad 〈 Equation ( 2 ) 〉$$

in which A is the area of the second inlet region Ai2 where a flow enters and the area of the second outlet region Ai2 where a flow comes out, and Vi2 is the speed of the second inlet velocity Vi1 passing through the second inlet region Ai2, and Vo2 is the speed of the second outlet velocity Vo2 passing through the second outlet region Ao2, and R is a resistance of the pair of second flow control structures 320, and p is a density of the molding member.

Accordingly, the first flow speed V1 of the central molding portion 45 and the second flow speed V2 of the outer molding portion 43 may be similar to each other. For example, the first flow speed V1 of the central molding portion 45 increases relatively as the central molding portion 45 passes between the pair of first flow control structures 310. However, the first flow speed V1 of the central molding portion 45 may relatively decrease again as the central molding portion 45 passes through the gap G provided under the semiconductor chip 200. Accordingly, the first flow speed V1 of the central molding portion 45 may be similar to the second flow speed V2 of the outer molding portion 43 that is relatively reduced as the outer molding portion 43 is in direct contact with at least one pair of second flow control structures 320.

Therefore, the center molding portion 45 may fill the gap G provided under the semiconductor chip 200 to prevent a void trap from occurring under the semiconductor chip 200.

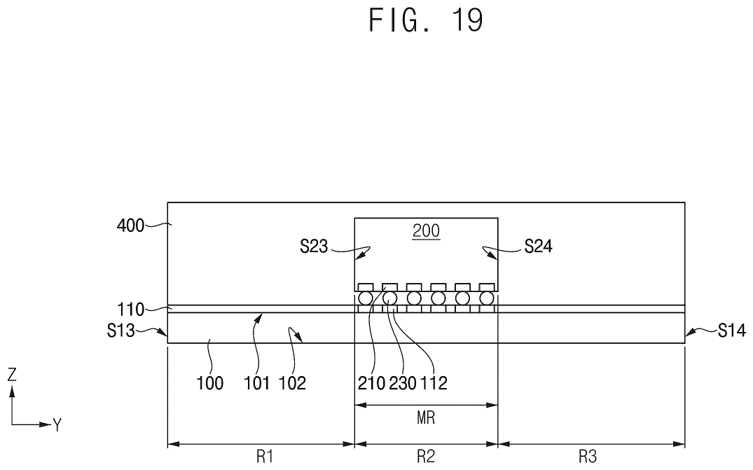

Referring to FIGS. 18 and 19, the molding material 40 may be injected at a constant speed during the molding process to cover the pair of first flow control structures 310, the semiconductor chip 200, and the at least one pair of second flow control structures 320 on the package substrate 100. Accordingly, the molding material 40 may fill the gap G provided under the semiconductor chip 200 to prevent a void trap from occurring under the semiconductor chip 200.

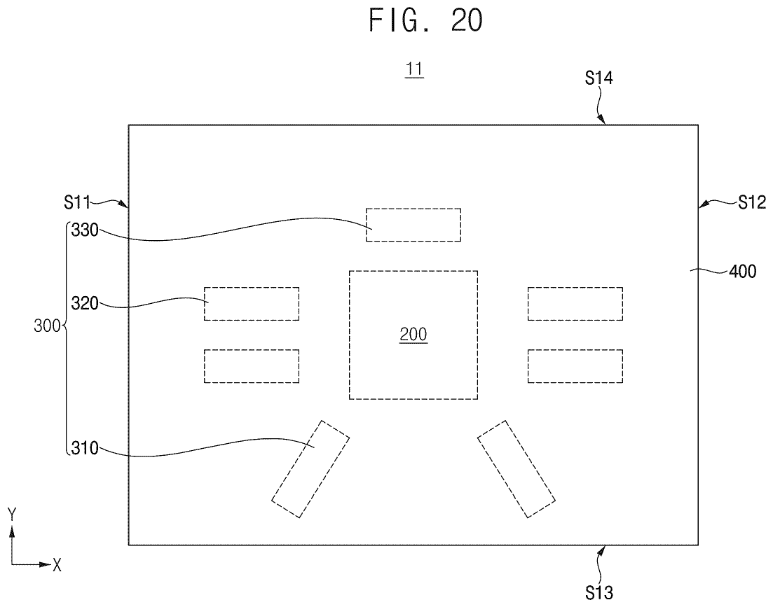

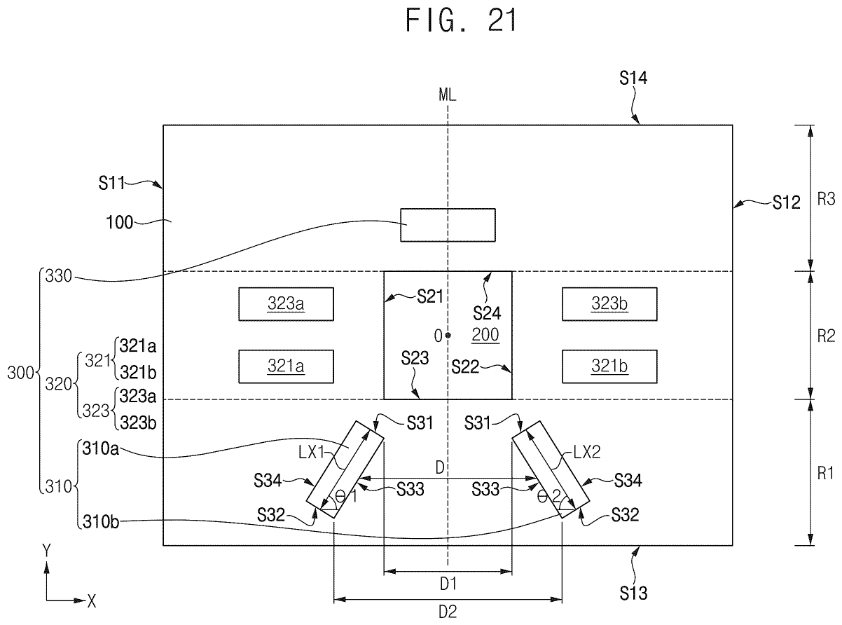

FIG. 20 is a plan view illustrating a method of manufacturing a semiconductor package in accordance with example embodiments. FIG. 21 is a plan view illustrating a semiconductor package of FIG. 20, wherein a molding member is omitted.

The semiconductor package is substantially the same as or similar to the semiconductor package described with reference to FIGS. 1 to 4 except for a third flow control structure. Accordingly, the same components are indicated by the same reference numerals, and repeated descriptions of the same components are omitted.

Referring to FIGS. 20 and 21, a semiconductor package 11 may include a package substrate 100, a semiconductor chip 200, a plurality of flow control structures 300, and a molding member 400. Additionally, the semiconductor package 10 may further include a plurality of conductive connection members 230. The plurality of flow control structures 300 may include a pair of first flow control structures 310, at least one pair of second flow control structures 320 and a third flow control structure 330. The plurality of flow control structures 300 may be structures to control a flow of a molding material injected during the molding process.

In example embodiments, the third flow control structure 330 may be provided on the package substrate 100. In an embodiment, the third flow control structure 330 may be a capacitor that is electrically connected to the package substrate 100. In this embodiment, the third flow control structure 330 may supply current to the semiconductor chip 200 or suppress noise in the circuit. Alternatively, the plurality of flow control structures 300 may be a stiffener that are configured to prevent the semiconductor package from a warpage or a dummy chip that are configured to only control the flow of the molding material. For example, in an embodiment, the pair of first flow control structures 310 and the third flow control structure 330 may be capacitors that are electrically connected to the package substrate 100 and the at least one pair of second flow control structures 320 may be stiffeners that prevent the semiconductor package from warpage.

The third flow control structure 330 may be disposed on the third region R3 of the package substrate 100. For example, the third flow control structure 330 may be disposed on the package substrate 100 to be spaced apart from the semiconductor chip 200 in the second direction (e.g., the Y direction). The third flow control structure 330 may be a structure that is configured to prevent the flow of the molding material from flowing back towards the semiconductor chip 200.

The third flow control structure 330 may be arranged in line with the semiconductor chip 200. For example, the third flow control structure 330 may be arranged to be spaced apart from the semiconductor chip 200 in the second direction (e.g., the Y direction) along the center line ML of the chip mounting region MR and may overlap the semiconductor chip 200 along the Y direction.

The third flow control structure 330 may be arranged parallel to the first direction (e.g., the X direction). For example, the third flow control structure 330 may have a rectangular shape with four sides. At least one of the four sides may be arranged parallel to the third substrate side portion S13 of the package substrate 100.

The third flow control structure 330 may prevent the molding material 40 from flowing back during the molding process. For example, the molding material 40 may be injected from the third substrate side portion S13 to the fourth substrate side portion S14 of the package substrate 100 along the second direction (e.g., the Y direction). The molding material 40 may be injected to cover the pair of first flow control structures 310, the semiconductor chip 200 and the at least one pair of second flow control structures 320. At this time, the third flow control structure 330 may prevent a portion of the injected molding material 40 from flowing in the opposite direction toward the gap G provided under the semiconductor chip 200. Accordingly, the third flow control structure 330 may prevent void traps from occurring under the flip chip.

However, embodiments of the present inventive concept are not necessarily limited thereto and the shape, size, arrangement, number, etc. of the third flow control structure 330 may change depending on the flow speed of the molding material injected during the molding process. Although only one flow control structure is shown in the drawings, it will be understood that the number, shape and arrangement of the flow control structures are provided as examples, and embodiments of the present inventive concept are not necessarily limited thereto.

In an embodiment, the semiconductor package may include semiconductor devices such as logic devices or memory devices. For example, the semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

The foregoing is illustrative of example embodiments and is not to be construed as limiting thereof. Although a few example embodiments have been described, those skilled in the art will readily appreciate that many modifications are possible in example embodiments without materially departing from the present inventive concept. Accordingly, all such modifications are intended to be included within the scope of example embodiments of the present inventive concept.

What is claimed is:

1. A semiconductor package, comprising:
a package substrate having a first region, a second region and third region sequentially arranged from a first side portion thereof to a second side portion thereof, the second region having a chip mounting region in a central region thereof, the package substrate including a plurality of substrate pads;
a semiconductor chip disposed in the chip mounting region of the package substrate, the semiconductor chip including a plurality of chip pads, wherein the semiconductor chip is mounted on the plurality of substrate pads of the package substrate via conductive connection members that are disposed on the plurality of chip pads of the semiconductor chip;
a pair of first flow control structures disposed in the first region of the package substrate, the pair of first flow control structures are disposed symmetrically on both sides along a center line passing through a center of the chip mounting region;
at least one pair of second flow control structures disposed in the second region of the package substrate, the at least one pair of second flow control structures are disposed symmetrically on both sides of the chip mounting region; and
a molding member on the package substrate, the molding member filling a gap between the semiconductor chip and the package substrate and covering the semiconductor chip, the pair of first flow control structures and the at least one pair of second flow control structures.

2. The semiconductor package of claim 1, wherein a spacing distance between the pair of first flow control structures is less than a spacing distance between the at least one pair of second flow control structures, respectively.

3. The semiconductor package of claim 1, wherein major axes of the pair of first flow control structures extend towards the center of the chip mounting region.

4. The semiconductor package of claim 1, wherein a spacing distance between the pair of first flow control structures gradually decreases towards the chip mounting region.

5. The semiconductor package of claim 1, wherein the at least one pair of second flow control structures have side portions that extend parallel to the first side portion and the second side portion of the package substrate.

6. The semiconductor package of claim 1, wherein the pair of first flow control structures and the at least one pair of second flow control structures have capacitors that are electrically connected to the package substrate.

7. The semiconductor package of claim 1, wherein the pair of first flow control structures have capacitors that are electrically connected to the package substrate, and the at least one pair of second flow control structures have stiffeners that prevent warpage of the package substrate.

8. The semiconductor package of claim 1, further comprising:
a third flow control structure disposed in the third region of the package substrate and arranged in a line with the semiconductor chip along the center line.

9. The semiconductor package of claim 8, wherein the third flow control structure includes a capacitor electrically connected to the package substrate.

10. The semiconductor package of claim 8, the pair of first flow control structures and the third flow control structures include capacitors that are electrically connected to the package substrate, and the at least one pair of second flow control structures include stiffeners that prevent warpage of the package substrate.

11. A semiconductor package, comprising:
a package substrate having a first region, a second region and third region sequentially arranged from a first side portion thereof to a second side portion thereof, the second region having a chip mounting region in a central region thereof, the package substrate including a plurality of substrate pads;
a semiconductor chip disposed in the chip mounting region of the package substrate, the semiconductor chip including a plurality of chip pads, wherein the semiconductor chip is mounted on the plurality of substrate pads of the package substrate via conductive connection members that are disposed on the plurality of chip pads of the semiconductor chip;
a pair of first flow control structures disposed in the first region of the package substrate, the pair of first flow control structures are disposed symmetrically on both sides along a center line passing through a center of the chip mounting region, wherein a spacing distance between the pair of first flow control structures gradually decreases towards the chip mounting region; and
a molding member on the package substrate, the molding member filling a gap between the semiconductor chip and the package substrate and covering the semiconductor chip and the pair of first flow control structures.

12. The semiconductor package of claim 11, wherein the pair of first flow control structures have capacitors that are electrically connected to the package substrate.

13. The semiconductor package of claim 11, wherein the pair of first flow control structures have stiffeners that prevent warpage of the package substrate.

14. The semiconductor package of claim 11, further comprising:
at least one pair of second flow control structures disposed in the second region of the package substrate and disposed symmetrically on both sides of the chip mounting region.

15. The semiconductor package of claim 14, wherein the spacing distance between the pair of first flow control structures is less than a spacing distance between the at least one pair of second flow control structures, respectively.

16. The semiconductor package of claim 14, wherein the pair of first flow control structures and the at least one pair of second flow control structures have capacitors that are electrically connected to the package substrate.

17. The semiconductor package of claim 11, further comprising:
a third flow control structure disposed in the third region of the package substrate and arranged in a line with the semiconductor chip along the center line.

18. The semiconductor package of claim 17, wherein the pair of first flow control structures and the third flow control structure have capacitors that are electrically connected to the package substrate.

19. A semiconductor package, comprising:
a package substrate having a first region, a second region and third region sequentially arranged from a first side portion thereof to a second side portion thereof, the second region having a chip mounting region in a central region thereof, the package substrate including a plurality of substrate pads;
a semiconductor chip disposed in the chip mounting region of the package substrate, the semiconductor chip including a plurality of chip pads, wherein the semiconductor chip is mounted on the plurality of substrate pads of the package substrate via conductive connection members that are disposed on the plurality of chip pads of the semiconductor chip;
a pair of first flow control structures disposed in the first region of the package substrate, the pair of first flow control structures are disposed symmetrically on both sides along a center line passing through a center of the chip mounting region, wherein a spacing distance between the pair of first flow control structures gradually decreases towards the chip mounting region;
at least one pair of second flow control structures disposed in the second region of the package substrate, the at least one pair of second flow control structures are disposed symmetrically on both sides of the chip mounting region;
a third flow control structure disposed in the third region of the package substrate and arranged in line with the semiconductor chip along the center line; and
a molding member on the package substrate, the molding member filling a gap between the semiconductor chip and the package substrate and covering the semiconductor chip, the pair of first flow control structures, the at least one pair of second flow control structures and the third flow control structure.

20. The semiconductor package of claim 19, wherein the pair of first flow control structures, the at least one pair of second flow control structures and the third flow control structures have capacitors that are electrically connected to the package substrate.
